(19) United States
(12) Patent Application Publication
(10) Pub. No.: US 2019/0002711 A1
(43) Pub. Date: Jan. 3, 2019

(54) THERMOELECTRIC (TE) INK FOR THREE-DIMENSIONAL (3D) PRINTED TE MATERIALS, TE MODULE INCLUDING 3D PRINTED TE MATERIAL, AND METHOD OF MANUFACTURING TE MODULE

(71) Applicant: UNIST(ULSAN NATIONAL INSTITUTE OF SCIENCE AND TECHNOLOGY), Republic of Korea (KR)

(72) Inventors: Jae Sung SON, Republic of Korea (KR); Fredrick KIM, Republic of Korea (KR)

(21) Appl. No.: 15/840,667

(22) Filed: Dec. 13, 2017

(30) Foreign Application Priority Data
Jun. 29, 2017 (KR) 10-2017-0082743

(51) Int. Cl. C09D 11/02; C09D 11/03; B33Y 10/00; B33Y 70/00; B33Y 80/00; B28B 1/00; H01L 35/16; H01L 35/08; H01L 35/32; H01L 35/34

(52) U.S. Cl. CPC C09D 11/02; C09D 11/03; B33Y 10/00; B33Y 70/00; H01L 35/34; B28B 1/001; H01L 35/16; H01L 35/08; H01L 35/32; B33Y 80/00

(57) ABSTRACT

A thermoelectric (TE) ink for TE materials, a TE module using the TE ink, and a method of manufacturing the TE module are provided. The TE ink may include an inorganic binder including chalcogenidometallate (ChaM), and TE particles including Bi₂₋ₓSbₓTe_{3-y}Se_{y} (0≤x≤2, 0≤y≤1).

### CROSS-REFERENCE TO RELATED APPLICATION

This application claims the benefit of Korean Patent Application No. 10-2017-0082743, filed on Jun. 29, 2017, in the Korean Intellectual Property Office, the disclosure of which is incorporated herein by reference.

### BACKGROUND

### 1. Field of the Invention

At least one example embodiment relates to a thermoelectric (TE) ink for TE materials, a TE module using the TE ink and a method of manufacturing the TE module. More particularly, at least one example embodiment relates to a TE ink that may be developed by forming a TE material and by effectively using a TE module even when a heat source has various shapes such as a curved surface other than a plane, relates to a TE material prepared from the TE ink using a three-dimensional (3D) printing technology, relates to a TE module including the TE material, and relates to a method of manufacturing the TE module.

### 2. Description of the Related Art

A thermoelectric (TE) effect is an effect of directly converting heat energy to electric energy and is attractive as a future energy source in terms of a possibility to provide continuous energy.

However, a low energy conversion efficiency of a TE material has always been an issue as a significant cause to limit an application of the TE effect. A performance of a TE material is represented by a dimensionless figure of merit, and a figure of merit, for example, a ZT value defined by Equation 1 below, is used. A higher ZT value indicates an excellent performance of the TE material.

$$ZT = \frac{{S}^{2} σ T}{K} \qquad [ Equation 1 ]$$

In Equation 1, ZT denotes a figure of merit, S denotes a Seebeck coefficient, σ denotes an electrical conductivity, T denotes an absolute temperature, and K denotes a thermal conductivity. An electrical conductivity and a Seebeck coefficient are inversely proportional to each other. For example, when the electrical conductivity increases, the Seebeck coefficient may decrease. In Equation 1, to increase a ZT value that is a figure of merit of a TE material, research has been conducted to increase the electrical conductivity and the Seebeck coefficient and to reduce the thermal conductivity.

In an actual application of the TE effect, a method to reduce a heat loss caused by an incomplete contact between a TE module and a surface of a heat source has been an issue. Since most of heat sources to which TE modules are applied have irregular shapes, it is difficult to realize an effective contact between a heat source and a conventional TE material having a planar structure, which leads to a great heat loss at all times. Due to the above heat loss, it is difficult to apply TE modules in industries.

For the above issues, according to a related art, a TE material is prepared to correspond to a shape of a heat source by a method, such as a printing technology using ink, to ensure a predetermined level of flexibility of an element in a manufacturing process. However, the printing technology has also at least two disadvantages. A first disadvantage is a decrease in a TE performance caused by an organic conductor binder that is necessarily included for an electrical connection between TE materials. A second disadvantage is an impossibility to form a TE material on a curved surface using a printing method according to the related art, such as a screen printing scheme or an inkjet scheme.

Therefore, there is a need in the field to study an implementation of a TE material applicable to a heat source with a curved surface and a new TE material having an excellent TE performance.

### SUMMARY

The present disclosure is to solve the foregoing problems, and an aspect provides a thermoelectric (TE) ink for TE materials which includes a new TE material with an excellent TE effect and which allows an element having a curved surface to be manufactured, a TE material prepared using the TE ink, a TE module, a TE material prepared using a 3D printing technology, and a method of manufacturing the TE module.

According to an aspect, there is provided a TE ink for TE materials, the TE ink including an inorganic binder including chalcogenidometallate (ChaM), and TE particles including Bi₂₋ₓSbₓTe_{3-y}Se_{y} (0≤x≤2, 0≤y≤1), wherein the inorganic binder is included in an amount of 1 to 50 parts by weight based on 100 parts by weight of the TE particles.

The ChaM may include Sb₂Te_{z} (3≤z≤7).

The inorganic binder may enclose at least one of the TE particles.

The TE ink may further include a wetting agent that includes glycerol, ethylene glycol or both.

According to another aspect, there is provided a TE module including an electrode, and a thermoelectric materials formed in contact with the electrode, and including a three-dimensional (3D) printed TE material, the TE material including an inorganic binder including ChaM and TE particles including Bi₂₋ₓSbₓTe_{3-y}Se_{y} (0≤x≤2, 0≤y≤1).

The ChaM may include Sb₂Te_{z} (3≤z≤7).

At least one surface of the TE module has a shape corresponding to a shape of a heat source.

The TE module may further include an adhesive layer formed between the electrode and the TE material and having a thickness of 0.1 millimeter (mm) to 3 mm.

The adhesive layer may include an adhesive resin including high conductive particles. The high conductive particles may include one of Ag, Ni, Sn, graphene, a carbon nanotube (CNT) and a carbon nanorod.

The adhesive layer may include an adhesive resin including high conductive particles. The high conductive particles may have one shape among a sphere, a nanorod, a nanotube and a nanowire. The high conductive particles may be arranged to form a conductive path in the adhesive resin.

A density of the TE material may be greater than or equal to 3.5 grams per cubic centimeter (g/cm³).

A room-temperature electrical conductivity of the TE material may range from 50,000 Siemens per meter (S/m) to 60,000 S/m, or a room-temperature Seebeck coefficient of the TE material may range from 100 microvolts per kelvin (μV/K) to 180 μV/K. When the TE material is an N-type TE material, a ZT value of the TE material measured at a room temperature may be greater than or equal to 0.3. When the TE material is a P-type TE material, the ZT value of the TE material may be greater than or equal to 0.6.

The TE module may be mounted on a heat source having a shape of a pipe. A cross section of the TE module may have a shape of at least a portion of a ring corresponding to the shape of the pipe.

The TEG may include a plurality of layers.

According to another aspect, there is provided a method of manufacturing a TE module, the method including forming a first electrode in a heat source, forming a 3D printed TE material on the first electrode using the TE ink, and forming a second electrode on the 3D printed TE material, wherein the first electrode has a shape corresponding to a shape of a portion of the heat source to which the first electrode is to be attached, and is attached to the heat source, and the 3D printed TE material has a shape corresponding to a shape of a portion of the first electrode to which the 3D printed TE material is to be attached, and is attached to the first electrode.

The forming of the 3D printed TE material may include performing 3D printing using the TE ink, drying the TE ink, and sintering the dried TE ink.

The method may further include forming a first adhesive layer after the forming of the first electrode, and forming a second adhesive layer after the forming of the 3D printed TE material. Each of the first adhesive layer and the second adhesive layer may have a thickness of 0.1 mm to 3 mm, and may include an adhesive resin including high conductive particles.

Additional aspects of example embodiments will be set forth in part in the description which follows and, in part, will be apparent from the description, or may be learned by practice of the disclosure.

### BRIEF DESCRIPTION OF THE DRAWINGS

These and/or other aspects, features, and advantages of the invention will become apparent and more readily appreciated from the following description of example embodiments, taken in conjunction with the accompanying drawings of which:

FIG. 1 is a diagram illustrating a structure in which a flat plate-shaped thermoelectric (TE) module according to a related art is formed on a pipe-shaped heat source;

FIG. 2 is a diagram illustrating a structure in which a TE module according to an example embodiment is formed on a pipe-shaped heat source;

FIG. 3 is a diagram illustrating a method of forming a TE module according to an example embodiment on a pipe-shaped heat source;

FIG. 4 is a flowchart illustrating a method of manufacturing a TE ink according to an example embodiment;

FIG. 5 is a flowchart illustrating a method of manufacturing a TE module including a 3D printed TE material according to an example embodiment;

FIG. 6 is a graph illustrating a density of a TE material including an inorganic binder (that is, a sintering aid) according to an example embodiment, and a density of a TE material that does not include the inorganic binder, under the same condition;

FIG. 7 is a graph illustrating a room-temperature electrical conductivity of a TE material including an inorganic binder (that is, a sintering aid) according to an example embodiment, and a room-temperature electrical conductivity of a TE material that does not include the inorganic binder, under the same condition;

FIG. 8 is a diagram illustrating a structure of an example in which a half ring-shaped TE module is fixed onto a pipe-shaped heat source by forming an adhesive layer;

FIG. 9 is a diagram illustrating a structure of a comparative example in which a flat plate-shaped TE module is fixed onto a pipe-shaped heat source by forming an adhesive layer in a contact portion between the flat plate-shaped TE module and the pipe-shaped heat source;

FIG. 10 is a graph illustrating an output voltage and output power calculated from a temperature difference for each of a half ring-shaped TE module and a flat plate-shaped TE module that are formed in cylindrical heat sources; and

FIG. 11 is a graph illustrating an absorbed heat rate and power generation efficiency based on a temperature difference for each of a half ring-shaped TE module and a flat plate-shaped TE module that are formed in cylindrical heat sources.

### DETAILED DESCRIPTION

Hereinafter, example embodiments of the present disclosure will be described in detail with reference to the accompanying drawings.

Various modifications may be made to the example embodiments. The example embodiments are not construed as limited to the disclosure and should be understood to include all changes, equivalents, and replacements within the idea and the technical scope of the disclosure.

The terminology used herein is for the purpose of describing particular example embodiments only and is not intended to be limiting of example embodiments. As used herein, the singular forms are intended to include the plural forms as well, unless the context clearly indicates otherwise. It should be further understood that the terms “comprises” and/or “comprising,” when used in this specification, specify the presence of stated features, integers, steps, operations, elements, components or a combination thereof, but do not preclude the presence or addition of one or more other features, integers, steps, operations, elements, components, and/or groups thereof.

Unless otherwise defined herein, all terms used herein including technical or scientific terms have the same meanings as those generally understood by one of ordinary skill in the art. Terms defined in dictionaries generally used should be construed to have meanings matching with contextual meanings in the related art and are not to be construed as an ideal or excessively formal meaning unless otherwise defined herein.

Regarding the reference numerals assigned to components in the drawings, it should be noted that the same components will be designated by the same reference numerals, wherever possible, even though they are shown in different drawings. Also, in describing of example embodiments, detailed description of well-known related structures or functions will be omitted when it is deemed that such description will cause ambiguous interpretation of the present disclosure.

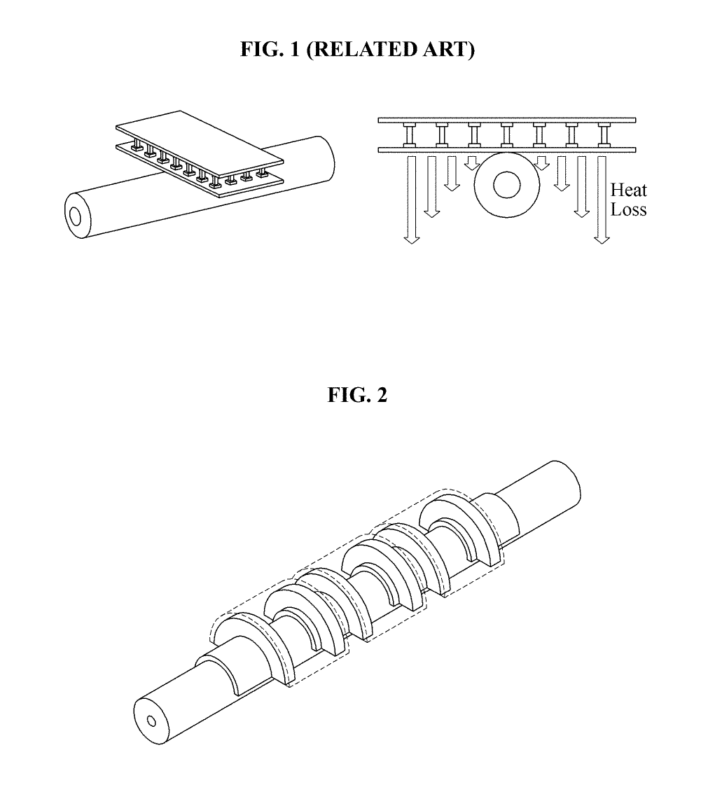

FIG. 1 is a diagram illustrating a structure in which a flat plate-shaped thermoelectric (TE) module according to a related art is formed on a pipe-shaped heat source.

According to the related art, since a TE material needs to be prepared to form a flat plate even when a heat source has a complex shape that includes, for example, a curved surface or an uneven portion, a contact area may decrease due to a distance from the heat source, which may lead to a decrease in a TE efficiency. In particular, in a process of studying a scheme to utilize waste heat such as hot water transported via a pipe, the above problem of the TE efficiency of the TE module may occur at all times.

As a result of research conducted to manufacture a TE module capable of effectively securing a TE performance by applying the TE module to various shapes of a heat source, the present inventor has developed a TE ink for TE materials that includes a TE material and that has a high TE efficiency, and developed a method of manufacturing a TE module capable of achieving a high TE performance using a three-dimensional (3D) printing technology even when the TE module is applied to various shapes of a heat source. Hereinafter, a configuration of each technology in addition to the TE ink and the TE module will be described in detail.

TE Ink for TE Materials

Using a TE ink according to an example embodiment, N-type and P-type TE materials may be formed to cover a surface of a heat source that has various shapes. Even when the heat source has a complex shape that includes, for example, a curved surface or an uneven portion, a TE module having a shape corresponding to the shape of the heat source may be manufactured using the TE ink. Thus, it is possible to secure a TE module capable of realizing a high TE performance regardless of a shape of a heat source.

According to an example embodiment, the TE ink may include an inorganic binder including a chalcogenidometallate (ChaM), and TE particles including Bi₂₋ₓSbₓTe_{3-y}Se_{y} (0≤x≤2, 0≤y≤1). The inorganic binder may be included in an amount of 1 to 50 parts (preferably 10 to 50 parts) by weight based on 100 parts by weight of the TE particles.

The TE ink may basically include BiTe-based TE particles. A BiTe-based material may be regarded as the best TE material near a room temperature, and results of research on various compositions and structures have been accumulated over a long period of time. In addition to the BiTe-based material, the TE ink may include quaternary TE particles including Bi₂₋ₓSbₓTe_{3-y}Se_{y} (0≤x≤2, 0≤y≤1). A composition and a composition ratio of the quaternary TE particles have been derived as a result of research of the present inventor, and correspond to a combination of TE materials that may exhibit an excellent TE performance at a relatively low temperature. The TE particles are not particularly limited in the present disclosure when the TE particles include Bi₂₋ₓSbₓTe_{3-y}Se_{y}. In Bi₂₋ₓSbₓTe_{3-y}Se_{y}, x may desirably be greater than or equal to 0 and less than or equal to 2, and y may desirably be greater than or equal to 0 and less than or equal to 1. Also, x and y may be 0, a natural number, or decimal.

In addition, more desirably, x may be 0 and y may range from 0.1 to 0.6. When x is 0 and y ranges from 0.1 to 0.6, an N-type TE material with a relatively high performance may be formed.

More desirably, x may range from 1.2 to 1.8 and y may be 0. When x ranges from 1.2 to 1.8 and y is 0, a P-type TE material with a relatively high performance may be formed.

The inorganic binder may include the ChaM, and may function to wrap and package at least one TE particle. The inorganic binder may be a colloid component. The inorganic binder may include a chalcogen metal ion, and may enhance a viscoelasticity of the TE ink. Also, the inorganic binder may provide electric charges to the TE particles through an electrostatic interaction with the TE particles, to form a TE material capable of achieving a high TE performance. Also, the inorganic binder may function to densely and firmly form a TE material during drying and sintering of the TE ink.

Ink for 3D printing in general fields other than a TE technology field may include an organic binder such as cellulose for a viscoelastic characteristic of the ink. However, because the organic binder may reduce an electrical conductivity between TE particles, it is unsuitable to use the organic binder for synthesis of a TE material in the TE technology field. In the present disclosure, the inorganic binder including ChaM may be used instead of the organic binder, which may be one of significant features of the present disclosure.

The inorganic binder may be included between the TE particles at a predetermined ratio, and may function to enhance a performance of a sintered TE material. When the amount of the inorganic binder is less than 10 parts by weight for 100 parts by weight of the TE particles, a TE performance enhancement effect that is intended by including the inorganic binder as described above may be insignificant. When the amount of the inorganic binder exceeds 50 parts by weight, a TE performance caused by a presence of quaternary TE particles may not be achieved due to an insufficient amount of TE particles including Bi_{2-y}Sb_{y}Te_{3-z}Se_{z} (0≤y≤2, 0≤z≤1). Thus, the inorganic binder may desirably be included in an amount of 15 to 50 parts by weight based on 100 parts by weight of the TE particles.

The ChaM may include Sb₂Te_{z} (3≤z≤7).

Since the inorganic binder including Sb₂Te_{z} (3≤z≤7) is included together, the TE ink including the quaternary TE particles may have a high density and a large crystal grain in a sintering process. This may correspond to a significant technical feature of the present disclosure that may realize a low thermal conductivity, a high ZT value, a high electrical conductivity and a high Seebeck coefficient of the TE material which are effects intended according to an example embodiment. For example, the inorganic binder may desirably include Sb₂Te₃.

The inorganic binder may refer to a component different from the TE particles. In the present disclosure, the inorganic binder may be different from the TE particles.

The inorganic binder may enclose at least one of the TE particles. In an example, the inorganic binder may be in a colloidal phase in the TE ink and include solid-phase TE particles. The inorganic binder may enhance a viscoelasticity of the TE ink by providing electric charges to the TE particles for an electrostatic interaction, and may function as a surface ligand of a nanoscale or microscale particle to stabilize particles in a solution. Also, the inorganic binder may fill a hole of a TE particle and may promote a particle growth and densification, to effectively increase an initial density of a TE material. Thus, due to the particle growth and densification, sintering may be effectively performed even when an external pressure is absent.

The TE ink may further include a wetting agent including glycerol, ethylene glycol or both.

By including the wetting agent, the TE ink may have an effect of securing a viscoelasticity suitable for 3D printing. The wetting agent may be included in an amount of 50 to 200 parts by weight based on 100 parts by weight of the TE particles.

TE Module Including 3D Printed TE Material

According to an example embodiment, a TE module including a thermoelectric materials manufactured using a 3D printing technology may be provided.

FIG. 2 illustrates a structure of a TE module according to an example embodiment formed on a pipe-shaped heat source.

In the TE module of FIG. 2, a first electrode may be formed on the pipe-shaped heat source, and an N-type TE material and a P-type TE material may be formed on the first electrode. Also, a second electrode may be formed on the N-type TE material and the P-type TE material.

Hereinafter, a structure of a TE module including a TE material manufactured using a 3D printing technology is described in detail with reference to FIG. 2.

The TE module may include an electrode, and a TE material. The TE material may be formed in contact with the electrode, and may include a 3D printed TE material. The 3D printed TE material may include an inorganic binder including ChaM, and TE particles including Bi₂₋ₓSbₓTe_{3-y}Se_{y} (0≤x≤2, 0≤y≤1).

The electrode may be formed using various metals. The electrode may be prepared using, for example, cooper (Cu). For example, a plurality of electrodes may be formed. In this example, the plurality of electrodes may be sandwiched between TE materials as shown in FIG. 2.

The TEG may include a TE material formed using the 3D printing technology. For example, a plurality of TEGs may be formed and include an N-type TE material and a P-type TE material. The TE materials may include an inorganic binder including ChaM, and TE particles including Bi₂₋ₓSbₓTe_{3-y}Se_{y} (0≤x≤2, 0≤y≤1).

The ChaM may include Sb₂Te_{z} (3≤z≤7).

Since the inorganic binder including Sb₂Te_{z} (3≤z≤7) is included together, a TE ink including quaternary TE particles may have a high density and a large crystal grain in a sintering process.

The inorganic binder may refer to a component different from the TE particles.

A surface of the TE module may have a shape corresponding to a shape of a heat source.

In the present disclosure, a 3D printed TEG and a TE module including the 3D printed TE materials may have a surface corresponding to a shape of a heat source. Thus, it is possible to manufacture a TE module with a high efficiency even when the TE module is applied to a heat source having a curved surface or an uneven portion. In the present disclosure, a shape corresponding to a shape of a heat source may refer to a shape that allows a complete attachment to a heat source with various shapes and allows a contact in a wide area at a high temperature of the heat source.

The TE module may further include an adhesive layer that is formed between the electrode and the TE materials and that has a thickness of 0.1 millimeter (mm) to 3 mm. When the thickness of the adhesive layer is less than 0.1 mm, an electrical cutoff and a loss of heat transfer by a gap may occur due to an unstable fixation between the electrode and the TE materials. When the thickness of the adhesive layer exceeds 3 mm, resistance to heat and electrical transmission may increase.

The adhesive layer may function to fix the 3D printed TE material to the electrode. For example, when a plurality of electrodes are formed and sandwiched between TE materials, a plurality of adhesive layers may also be formed between the electrodes and the TE materials.

In an example, the adhesive layer may include an adhesive resin including high conductive particles. In this example, the high conductive particles may include one of Ag, Ni, Sn, graphene, a carbon nanotube (CNT) and a carbon nanorod. For example, the adhesive layer may include an Ag-epoxy adhesive resin. In this example, Ag may function as an electrical solder to electrically connect the electrode and the TE material.

Typically, a Bi-based or Sb-based low-melting point metal solder may be used to connect an electrode and a TE material. However, according to an example embodiment, a TE module may need to be manufactured with various shapes to correspond to a shape of a heat source. In particular, when a TE module having a shape including a curved surface is manufactured, a Bi-based or Sb-based low-melting point metal solder that is generally used may fall down. According to an example embodiment, Ag-epoxy may be used to form the adhesive layer to solve the above problems. The adhesive layer may form a hard conductive layer through a slight heat treatment, and may function to fix the electrode and the TE material.

In another example, the adhesive layer may include an adhesive resin including high conductive particles. In this example, the high conductive particles may have one of shapes, for example, a sphere, a nanorod, a nanotube and a nanowire, and may be arranged to form a conductive path in the adhesive resin. In particular, when particles have conductivity in a predetermined direction, for example, a nanorod, a nanotube or a nanowire, an electrical path may be more effectively formed.

A density of the TE material may be greater than or equal to 3.5 grams per cubic centimeter (g/cm³).

The TE material may have a significantly high density in comparison to Bi₂Te₃-based TE materials prepared according to a related art. Thus, the TE module according to an example embodiment may have a high TE performance, which may correspond to a feature of the present disclosure to enable a differentiation from other TE modules.

For example, the TE material may include crystal grains with an average cross-sectional area of 1 square micrometer (μm²) to 2,500 μm². A TE material prepared according to an example embodiment may include crystal grains with a large average cross-sectional area, in comparison to the Bi₂Te₃-based TE materials prepared according to the related art. Thus, it is possible to realize an excellent TE performance of the TE module, which may correspond to another key feature of the present disclosure to enable a differentiation from other TE modules.

A room-temperature electrical conductivity of the TE material may range from 50,000 Siemens per meter (S/m) to 60,000 S/m, or a room-temperature Seebeck coefficient of the TE material may range from 100 microvolts per kelvin (μV/K) to 180 μV/K. When the TE material is an N-type TE material, a ZT value measured at a room temperature may be greater than or equal to 0.3. When the TE material is a P-type TE material, the ZT value may be greater than or equal to 0.6.

The TE material may have a high electrical conductivity, a high Seebeck coefficient and a low thermal conductivity in comparison to the Bi₂Te₃-based TE materials prepared according to the related art, which may indicate an excellent TE performance of the TE module and may correspond to another key feature of the present disclosure to enable a differentiation from other TE modules.

The TE module may be mounted on a heat source having a shape of a pipe. A cross section of the TE module may have a shape of at least a portion of a ring corresponding to the shape of the pipe. In other words, the TE module may have a shape in a close contact with the heat source, to further enhance a power generation efficiency.

The TEG may include a plurality of layers.

For example, the TEG may have a structure in which a plurality of layers are laminated. In this example, the plurality of layers may be sequentially laminated one by one using a 3D printer.

Method of Manufacturing TE Ink

According to an example embodiment, a method of manufacturing the above-described TE ink may be provided.

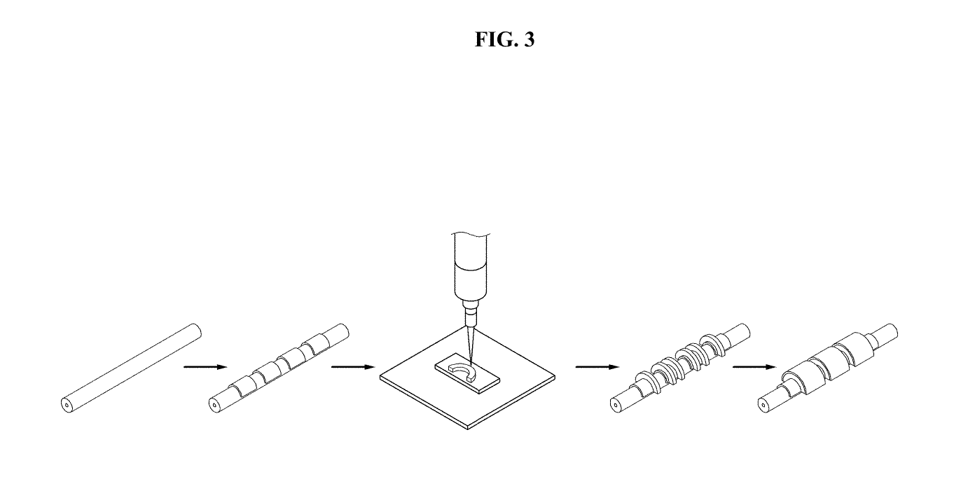

FIG. 3 illustrates a process of attaching a lower metal electrode to a pipe-shaped heat source, forming an N-type TE material and a P-type TE material that each have a shape of a half ring using a 3D printing technology, attaching each of the N-type TE material and the P-type TE material onto the lower metal electrode using an adhesive layer, and attaching an upper metal electrode onto the N-type TE material and the P-type TE material using the adhesive layer.

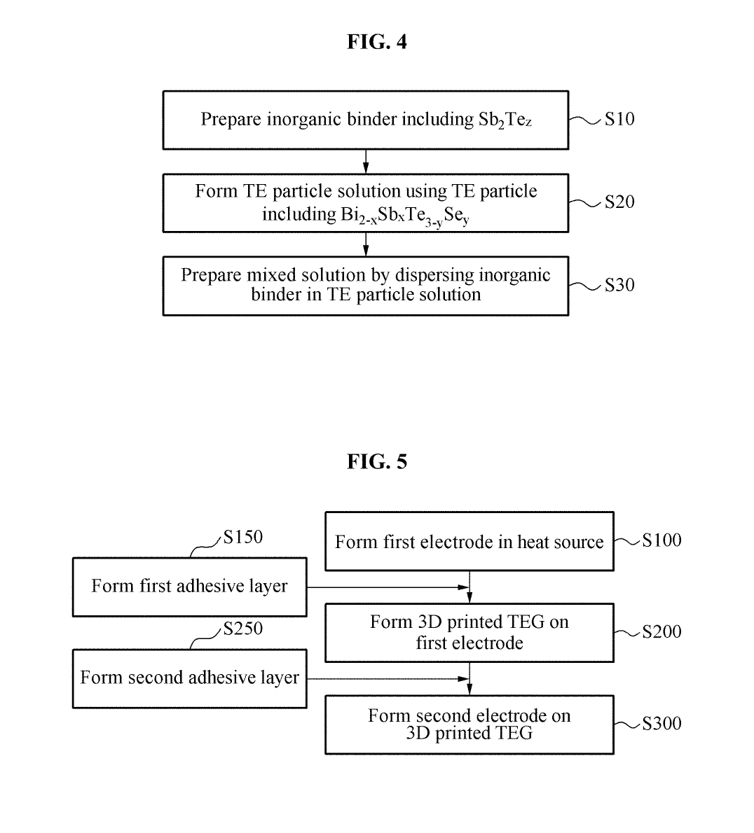

FIG. 4 is a flowchart illustrating a method of manufacturing a TE ink according to an example embodiment.

Hereinafter, the method of FIG. 4 is described in detail.

The method of FIG. 4 may include operation S10 of preparing an inorganic binder including Sb₂Te_{z} (3≤z≤7), operation S20 of forming a TE particle solution by dissolving TE particles including Bi₂₋ₓSbₓTe_{3-y}Se_{y} (0≤x≤2, 0≤y≤1) in a solvent, and operation S30 of preparing a mixed solution by dispersing, in the TE particle solution, the prepared inorganic binder that is included in an amount of 1 to 50 parts (preferably 10 to 50 parts) by weight based on 100 parts by weight of the TE particles.

In operation S10, the inorganic binder including Sb₂Te_{z} (3≤z≤7) is provided. When the inorganic binder is prepared, the TE particle solution may be formed by dissolving the TE particles in the solvent. The solvent may desirably include, for example, a polar solvent. The mixed solution may be formed by dispersing an appropriate amount of the inorganic binder in the TE particle solution. In the mixed solution, the inorganic binder and the TE particles may form a stable suspension state without a phase separation.

According to an example embodiment, the prepared inorganic binder may be dispersed in a solvent, and then TE particles may be dissolved in the solvent, to form a mixed solution. The inorganic binder may be mixed with the TE particles in a polar solvent, to form a TE ink, and ultimately to form a TE material having an excellent TE performance by performing sintering to have a high density and a large crystal grain.

For example, operation S10 may include preparing a solution including antimony (Sb) and tellurium (Te) by dissolving a Sb precursor and a Te precursor in a solvent. In this example, the solvent may alkylthiol, alkyldithiol or both, and alkylamine, alkyldiamine or both.

The Sb precursor and the Te precursor may be a Sb bulk and a Te bulk, respectively. The solvent in which the Sb precursor and the Te precursor are dissolved may include, for example, alkylthiol, alkyldithiol or both, and alkylamine, alkyldiamine or both. Also, the solvent may be a hydrazine-free solvent. Hydrazine (N₂H₄) that is typically used for dissolution of a TE material may be excluded from the solvent in operation S10 due to a high toxicity of the hydrazine.

The Sb precursor and the Te precursor dissolved in the solution including the Sb and Te may be present as ionic particles. An appropriate heat treatment at about 100° C., and a room-temperature drying process may be performed, and accordingly the inorganic binder including Sb₂Te_{z} (3≤z≤7) may be secured.

The inorganic binder may refer to a component different from the TE particles.

The TE ink may include quaternary TE particles including Bi₂₋ₓSbₓTe_{3-y}Se_{y} (0≤x≤2, 0≤y≤1) in addition to a BiTe-based material. A composition and a composition ratio of the quaternary TE particles have been derived as a result of research, and correspond to a combination of TE materials that may exhibit an excellent TE performance at a relatively low temperature. The TE particles are not particularly limited in the present disclosure when the TE particles include Bi₂₋ₓSbₓTe_{3-y}Se_{y}.

In Bi₂₋ₓSbₓTe_{3-y}Se_{y}, more desirably, x may be 0 and y may range from 0.1 to 0.6. For example, when x is 0 and y ranges from 0.1 to 0.6, an N-type TE material with a relatively high performance may be formed.

Also, more desirably, x may range from 1.2 to 1.8 and y may be 0. For example, when x ranges from 1.2 to 1.8 and y is 0, a P-type TE material with a relatively high performance may be formed.

The method of FIG. 4 may further include mixing a wetting agent including glycerol, ethylene glycol or both in the mixed solution.

By including the wetting agent, the TE ink may have an effect of securing a viscoelasticity suitable for 3D printing. The wetting agent may be included in an amount of 50 to 200 parts by weight based on 100 parts by weight of the TE particles.

Method of Manufacturing TE Module Including 3D Printed TE Material

According to an example embodiment, a method of manufacturing a TE module including a TE material formed by a 3D printing technology using the above-described TE ink may be provided.

FIG. 3 illustrates a method of forming a TE module according to an example embodiment in a pipe-shaped heat source.

As described above, referring to FIG. 3, the lower metal electrode is attached to the pipe-shaped heat source, and the N-type TE material and the P-type TE material that each have a shape of a half ring are formed using the 3D printing technology. Each of the N-type TE material and the P-type TE material is attached onto the lower metal electrode using an adhesive layer, and an upper metal electrode is attached onto each of the N-type TE material and the P-type TE material using the adhesive layer.

FIG. 5 is a flowchart illustrating a method of manufacturing a TE module according to an example embodiment.

Hereinafter, a method of manufacturing a TE module including a TE material formed by a 3D printing technology using a TE ink is described in detail with reference to FIG. 5.

The method of FIG. 5 may include operation S100 of forming a first electrode in a heat source, operation S200 of forming a 3D printed TE material on the first electrode using the TE ink, and operation S300 of forming a second electrode on the 3D printed TE material. The first electrode may have a shape corresponding to a shape of a portion of the heat source to which the first electrode is to be attached, and may be attached to the heat source. The 3D printed TE material may have a shape corresponding to a shape of a portion of the first electrode to which the 3D printed TE material is to be attached, and may be attached to the first electrode. For example, the TE module of FIG. 3 may include a first electrode formed on a heat source, a TE material formed on the first electrode, and a second electrode formed on the TE material. In this example, the TE material may be a TE module that is 3D printed by the above-described method, and the 3D printing technology is not particularly limited in the present disclosure.

Components of the TE particles and the inorganic binder may be selected to realize an appropriate viscoelasticity to perform 3D printing and a TE performance with a high efficiency even when a TE module is manufactured by 3D printing, and may be a feature in the present disclosure.

The 3D printed TE material may be manufactured by performing 3D printing using the TE ink, drying the TE ink, and sintering the dried TE ink.

The 3D printing may be performed using a 3D printing device configured to control a temperature and pressure. The 3D printing may be performed at a temperature of 100° C. to 200° C. A scheme used for the 3D printing is not particularly limited in the present disclosure when the scheme is a printing method to form a TE material with a 3D structure. Thus, it is possible to manufacture, using a simple and easy scheme, a TE material that has a shape corresponding to a shape of a heat source having a curved surface or an uneven portion and that is not implemented by a scheme according to the related art. The above TE material may have a wide contact surface corresponding to the shape of the heat source, and thus it is possible to secure an excellent TE performance.

In the drying of the TE ink, the TE ink may be dried and solidified. The drying may be performed at a temperature of 50° C. to 200° C., desirably at a temperature of 90° C. to 200° C., and more desirably at a temperature of 90° C. to 120° C. When the temperature for the drying is lower than 50° C., the TE ink may not be completely dried. When the temperature for the drying exceeds 200° C., a crack may be formed due to suddenly drying at a high temperature, which may lead to a reduction in a performance.

For example, the drying may desirably be performed a plurality of times in the above temperature range. In this example, the drying may more desirably be performed by initially setting a low temperature and gradually increasing the temperature. Thus, it is possible to minimize a formation of a crack during the drying, and to manufacture a TE module with a high performance.

In the sintering, the solidified TE ink may be further densified to increase a density and may be organized as a TE material with a high TE performance. The sintering may be performed at a temperature of 350° C. to 550° C. The sintering may be performed at various gas atmospheres, however, desirably performed at a nitrogen atmosphere. The temperature for the sintering may desirably range from 400° C. to 450° C., and more desirably range from 430° C. to 450° C. When the temperature for the sintering increases, a size of a crystal grain and a density of the sintered TE ink may gradually increase. When the temperature for the sintering exceeds 550° C., Te may be additionally evaporated in addition to a solvent. Accordingly, the density of the sintered TE ink may decrease, and a performance of the TE material may decrease due to a lack of the Te.

Through the sintering, a volume of the TE ink may decrease. For example, when a TE material with a shape of a half ring is printed and sintered as shown in FIG. 3, each of a width and a thickness of the TE material may decrease by about 10% to 30%.

In an example, the TE material may include a plurality of layers. In this example, in operation S200, the plurality of layers may be sequentially laminated to form the TEG.

In another example, the TE material may have a structure in which a plurality of layers are laminated. In this example, the plurality of layers may be sequentially laminated one by one using a 3D printer.

The method of FIG. 5 may further include operation S150 of forming a first adhesive layer after operation S100, and operation S250 of forming a second adhesive layer after operation 200. Each of the first adhesive layer and the second adhesive layer may have a thickness of 0.1 mm to 3 mm, and may include an adhesive resin including high conductive particles.

The first adhesive layer and the second adhesive layer may function to fix the 3D printed TEG to the first electrode and the second electrode. For example, when a plurality of electrodes are formed and sandwiched between TE materials, a plurality of adhesive layers may also be formed between the electrodes and the TEGs. As described above with reference to FIG. 4, the TE module may include at least one electrode and a TE material. Adhesive layers (*The first adhesive layer and the second adhesive layer may be formed between the first electrode and the TE material and between the second electrode and the TE material.

For example, the adhesive layer may include Ag-epoxy. The Ag-epoxy may function as an electrical solder to electrically connect an electrode to a TE material. When Ag-epoxy is used, an electrode and a TE material may be effectively fixed despite various shapes of TE modules.

### Example

To prepare an inorganic binder including Sb₂Te₃, 0.32 g of Sb and 0.68 g of Te were added to a mixed solvent of 2 ml of ethanethiol and 8 ml of ethylenediamine, and completely dissolved through stirring for 6 hours. The Sb₂Te₃ was precipitated by adding 40 ml of acetronitrile into the solution, followed by a centrifugation at 7,500 rpm for 10 minutes. A sintering aid including the precipitated Sb₂Te₃ was acquired.

TE particles were prepared through a mechanical alloying process. Bi, Sb, Te and Se powders were measured at a stoichiometric ratio under an N₂ atmosphere, to correspond to an N-type BTS (Bi_{2.0}Te_{2.7}Se_{0.3}) and a P-type BST (Bi_{0.4}Sb_{1.6}Te_{3.0}), and a ball mill process was performed for 4 hours to 5 hours using stainless steel balls (two balls with a diameter of 0.5 inch and four balls with a diameter of 0.25 inch). A synthesized BTS and an alloy composition of the synthesized BTS were verified by an XRD analysis. The BTS and agglomerated BTS particles were removed by performing a sieving process with a sieve diameter of 45 μm. A resultant from which BTS and agglomerated BTS particles were removed was dissolved in a polar solvent including 3.6 g of glycerol and 0.4 g of ethylene glycol, and a sonication was performed for 1 hour, to form a viscous TE particle solution.

The inorganic binder including Sb₂Te₃ was dispersed in the TE particle solution in which the N-type BTS and P-type BST are dissolved, and a sonication was performed for 1 hour, to acquire a TE ink including a sintering aid.

Experiment to Verify Effect of Inorganic Binder

The acquired TE ink was applied, dried and sintered, to form a TE material layer corresponding to the example.

The drying was performed for 30 minutes at 90° C., for 30 minutes at 120° C., and for 30 minutes at 160° C., sequentially. The sintering was performed for about 10 minutes to 30 minutes at a temperature of 350° C. to 450° C. All the above operations were performed in a chamber with sufficient nitrogen gas.

For a comparison to the example, a TE material layer corresponding to a comparative example was formed using the same method as in the example except that the inorganic binder was not included.

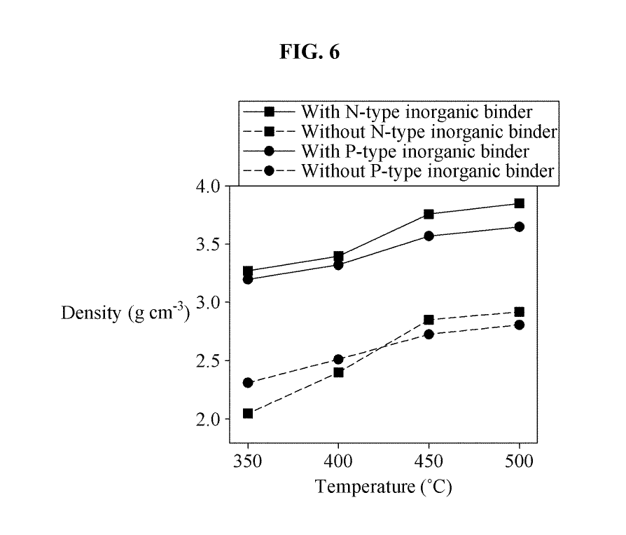

FIG. 6 is a graph illustrating a density of a TE material including an inorganic binder (that is, a sintering aid) according to an example embodiment, and a density of a TE material that does not include the inorganic binder, under the same condition.

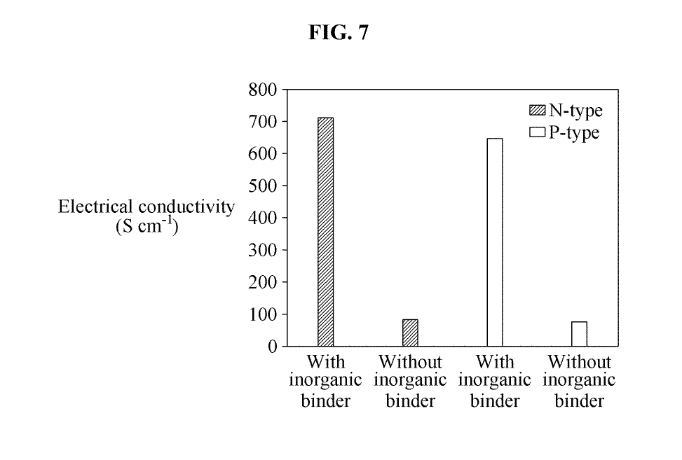

FIG. 7 is a graph illustrating a room-temperature electrical conductivity of a TE material including an inorganic binder (that is, a sintering aid) according to an example embodiment, and a room-temperature electrical conductivity of a TE material that does not include the inorganic binder, under the same condition.

Referring to FIGS. 6 and 7, when the TE material includes the inorganic binder, the density may increase and a high electrical conductivity may be realized, and thus it is possible to secure an excellent TE performance. When a TE material is prepared using a TE ink including an inorganic binder provided in the present disclosure, a density of particles may increase in a sintering process, and thus a density of the TE material and an average cross-sectional area of crystal grains may increase.

Experiment to Verify Performance of TE Module

Using the acquired TE ink, a TE material with a shape of a half ring was secured using a 3D printing technology to a size that is designed in advance to correspond to a shape of a heat source. Drying and sintering were sequentially performed, to form a TE material of the TE module corresponding to the example.

An N-type TE material and a P-type TE material were fixed, using Ag-epoxy, onto a first copper electrode layer attached to a pipe-shaped heat source. A second copper electrode layer was fixed onto the N-type TE material and the P-type TE material using the Ag-epoxy, to manufacture a TE module provided in the present disclosure.

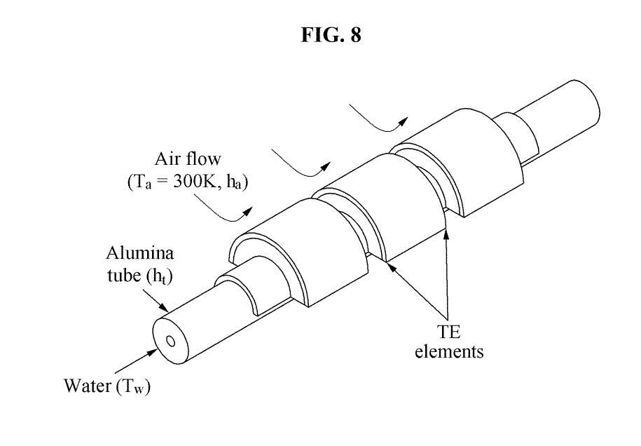

FIG. 8 is a diagram illustrating a structure of the example in which a half ring-shaped TE module is fixed onto a pipe-shaped heat source by forming an adhesive layer.

A TE module corresponding to the comparative example was manufactured using the same material as in the example except that the TE module had a shape of a flat plate.

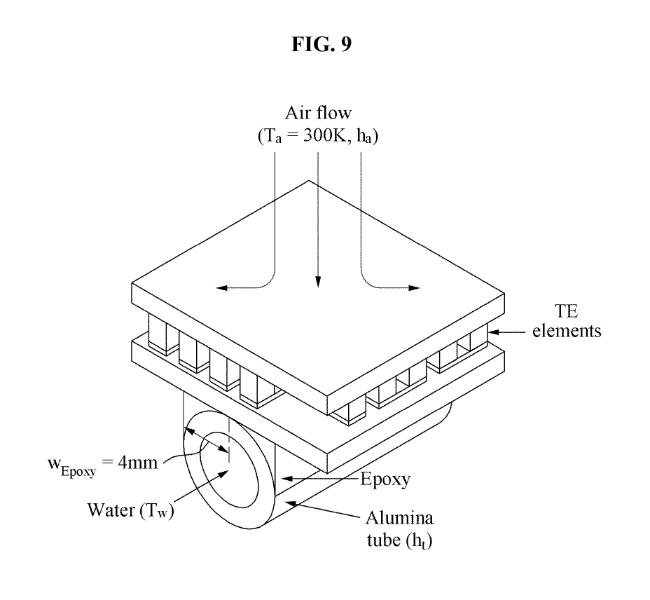

FIG. 9 is a diagram illustrating a structure of the comparative example in which a flat plate-shaped TE module is fixed onto a pipe-shaped heat source by forming an adhesive layer in a contact portion between the flat plate-shaped TE module and the pipe-shaped heat source.

An output voltage, an output power, a heat rate and a power generation efficiency of each of the TE module of the example and the TE module of the comparative example were measured at an external temperature of 300 K when hot water at the same temperature is flowing in the pipe-shaped heat sources, to evaluate performances of the TE modules.

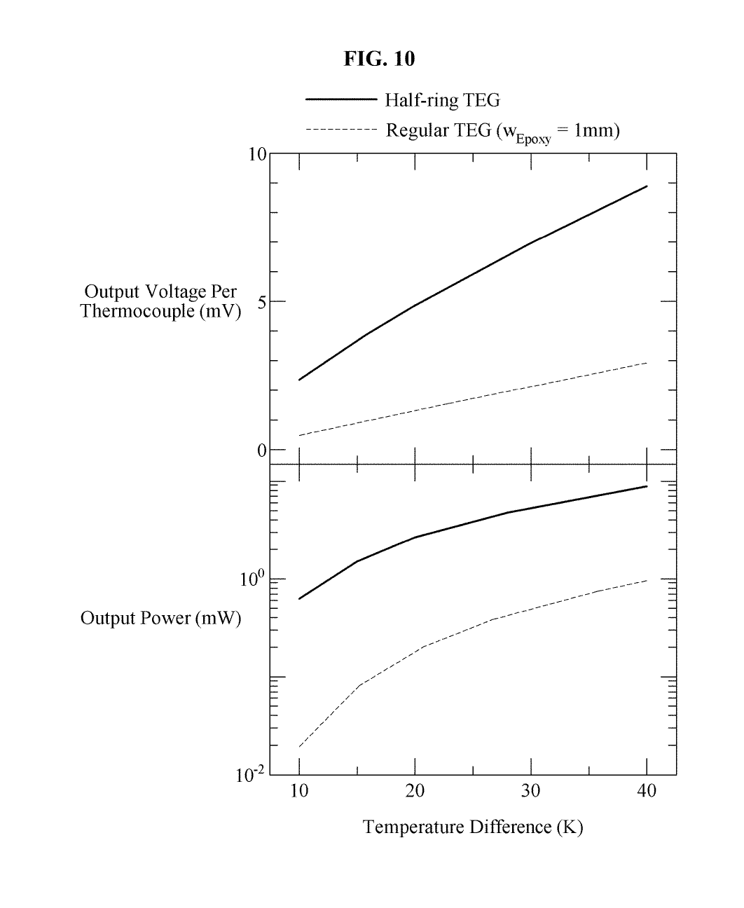

FIG. 10 is a graph illustrating an output voltage and output power calculated from a temperature difference for each of a half ring-shaped TE module and a flat plate-shaped TE module that are formed in cylindrical heat sources.

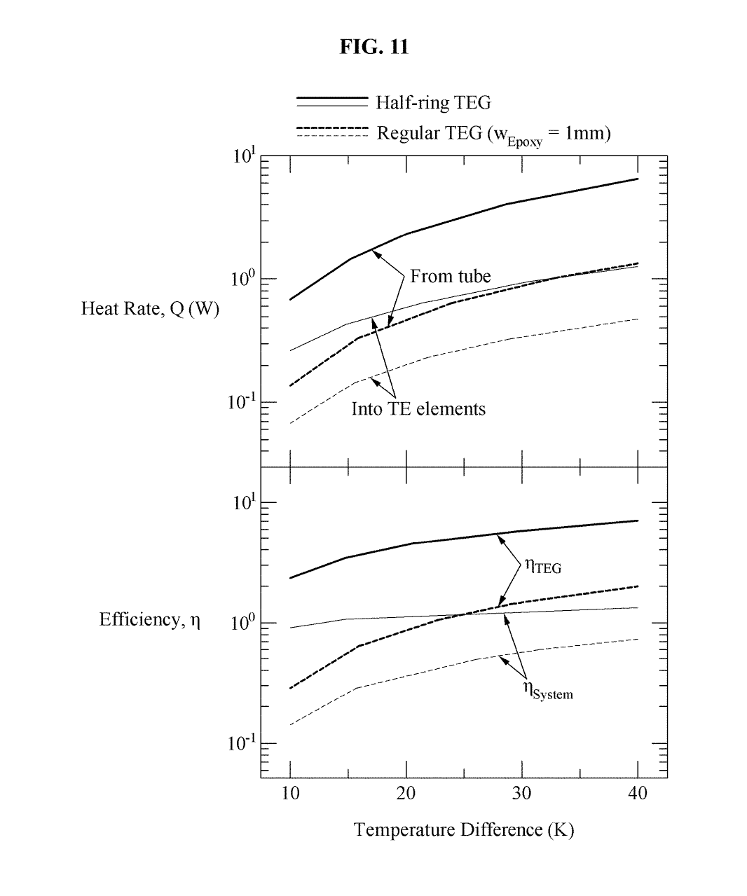

FIG. 11 is a graph illustrating an absorbed heat rate and power generation efficiency based on a temperature difference for each of a half ring-shaped TE module and a flat plate-shaped TE module that are formed in cylindrical heat sources.

Referring to FIGS. 10 and 11, it is found that the TE module of the example manufactured to have a shape corresponding to a shape of the heat source using a 3D printing technology has an excellent performance in comparison to the TE module of the comparative example.

According to example embodiments, a TE ink may include an inorganic binder and TE particles that exhibit an excellent TE performance at the room temperature, and accordingly have a high TE performance. Also, it is possible to manufacture a TE material with various shapes including a plane and a curved surface using a 3D printing technology while maintaining a high TE performance, and possible to implement a TE module.

While this disclosure includes specific examples, it will be apparent to one of ordinary skill in the art that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

What is claimed is:

1. A thermoelectric (TE) ink for TE materials, the TE ink comprising:
an inorganic binder comprising chalcogenidometallate (ChaM); and
TE particles comprising Bi₂₋ₓSbₓTe_{3-y}Se_{y} (0≤x≤2, 0≤y≤1),
wherein the inorganic binder is included in an amount of 1 to 50 parts by weight based on 100 parts by weight of the TE particles.

2. The TE ink of claim 1, wherein the ChaM comprises Sb₂Te_{z} (3≤z≤7).

3. The TE ink of claim 1, wherein the inorganic binder encloses at least one of the TE particles.

4. The TE ink of claim 1, further comprising:
a wetting agent comprising glycerol, ethylene glycol or both.

5. A thermoelectric (TE) module comprising:
an electrode; and
a thermoelectric device formed in contact with the electrode, and comprising a three-dimensional (3D) printed TE material, the 3D printed TE material comprising an inorganic binder comprising chalcogenidometallate (ChaM), and TE particles comprising Bi₂₋ₓSbₓTe_{3-y}Se_{y} (0≤x≤2, 0≤y≤1).

6. The TE module of claim 5, wherein the ChaM comprises Sb₂Te_{z} (3≤z≤7).

7. The TE module of claim 5, wherein at least one surface of the TE module has a shape corresponding to a shape of a heat source.

8. The TE module of claim 5, further comprising:
an adhesive layer formed between the electrode and the TE materials and having a thickness of 0.1 millimeter (mm) to 3 mm.

9. The TE module of claim 8, wherein
the adhesive layer comprises an adhesive resin comprising high conductive particles, and
the high conductive particles comprise one selected from the group consisting of Ag, to Ni, Sn, graphene, a carbon nanotube (CNT) and a carbon nanorod.

10. The TE module of claim 8, wherein
the adhesive layer comprises an adhesive resin comprising high conductive particles,
the high conductive particles have one shape selected from the group consisting of a sphere, a nanorod, a nanotube and a nanowire, and
the high conductive particles are arranged to form a conductive path in the adhesive resin.

11. The TE module of claim 5, wherein a density of the TE material is greater than or equal to 3.5 grams per cubic centimeter (g/cm³).

12. The TE module of claim 5, wherein
a room-temperature electrical conductivity of the TE material ranges from 50,000 Siemens per meter (S/m) to 60,000 S/m,
a room-temperature Seebeck coefficient of the TE material ranges from 100 microvolts per kelvin (μV/K) to 180 μV/K, or
a ZT value measured at a room temperature is greater than or equal to 0.3 when the TE material is an N-type TE material, and the ZT value is greater than or equal to 0.6 when the TE material is a P-type TE material.

13. The TE module of claim 5, wherein
the TE module is mounted on a heat source having a shape of a pipe, and
a cross section of the TE module has a shape of at least a portion of a ring corresponding to the shape of the pipe.

14. The TE module of claim 5, wherein the TE material comprises a plurality of layers.

15. A method of manufacturing a thermoelectric (TE) module, the method comprising:
forming a first electrode in a heat source;
forming a three-dimensional (3D) printed thermoelectric materials on the first electrode using the TE ink of claim 1; and
forming a second electrode on the 3D printed TE materials,
wherein the first electrode has a shape corresponding to a shape of a portion of the heat source to which the first electrode is to be attached, and is attached to the heat source, and the 3D printed TE materials has a shape corresponding to a shape of a portion of the first electrode to which the 3D printed TE materials is to be attached, and is attached to the first electrode.

16. The method of claim 15, wherein the forming of the 3D printed TEG comprises:
performing 3D printing using the TE ink of claim 1;
drying the TE ink; and
sintering the dried TE ink.

17. The method of claim 15, further comprising:
forming a first adhesive layer after the forming of the first electrode; and
forming a second adhesive layer after the forming of the 3D printed TE materials,
wherein each of the first adhesive layer and the second adhesive layer has a thickness of 0.1 millimeter (mm) to 3 mm, and comprises an adhesive resin comprising high conductive to particles.
